(19) United States
(12) Patent Application Publication
(10) Pub. No.: US 2009/0315136 A1
(43) Pub. Date: Dec. 24, 2009

(54) PHOTOELECTRIC CONVERSION ELEMENT AND SOLID-STATE IMAGING DEVICE

(75) Inventor: Masayuki HAYASHI, Kanagawa (JP)

Correspondence Address: SUGHRUE-265550, 2100 PENNSYLVANIA AVE. NW, WASHINGTON, DC, 20037-3213, US

(73) Assignee: FUJIFILM CORPORATION, Tokyo (JP)

(21) Appl. No.: 12/487,704

(22) Filed: Jun. 19, 2009

(30) Foreign Application Priority Data
Jun. 20, 2008 (JP) 2008-161770

(51) Int. Cl. H01L 27/142

(52) U.S. Cl. 257/440; 257/E27.123

(57) ABSTRACT

A photoelectric conversion element includes a pair of electrodes, a photoelectric conversion layer provided between the pair of electrodes and a stress buffer layer provided between the photoelectric conversion layer and at least one of the electrodes, and the stress buffer layer has a stack structure comprising a crystalline sublayer.

### CROSS-REFERENCE TO RELATED APPLICATIONS

This application claims the benefit of Japanese Patent Application JP 2008-161770, filed Jun. 20, 2008, the entire content of which is hereby incorporated by reference, the same as if set forth at length.

### FIELD OF THE INVENTION

This invention relates to a photoelectric conversion element having a pair of electrodes and a photoelectric conversion layer therebetween and a solid-state imaging device having an array of a large number of the photoelectric conversion elements.

### BACKGROUND OF THE INVENTION

A solid state imaging device having an array of photoelectric conversion elements is known, the photoelectric conversion element having a pair of electrodes and a photoelectric conversion layer of an organic or inorganic material between the electrodes.

A photoelectric conversion element having an additional functional layer, such as a blocking layer (a carrier injection barrier to prevent dark current) or a crystallization preventive layer, between the electrode and the photoelectric conversion layer is also known. Known photoelectric conversion elements having a photoelectric conversion layer between a pair of electrodes are disclosed, e.g., in JP 9-36406A and JP 2008-72090A (corresponding to US2008/0035965A1).

### SUMMARY OF THE INVENTION

There is concern that the stress generated in the electrode can cause cracking, delamination or deformation at the interface between the electrode and the photoelectric conversion layer or between the electrode and the blocking layer, resulting in deterioration of photoelectric conversion performance. In particular, in a configuration having a photoelectric conversion layer of an organic material and a transparent electrode, e.g., of ITO formed on the photoelectric conversion layer as a counter electrode, the stress in the transparent electrode can crack or wrinkle the photoelectric conversion layer. This leads to reduction of photoelectric conversion performance, such as an increase in dark current. Although the stress of the transparent electrode could be lessened by reducing its thickness, this results in an increase of the resistance of the transparent electrode, which will be followed by remarkable reductions in voltage or response speed especially when the photoelectric conversion element has a large area and invite reduction of the photoelectric conversion performance as a result.

JP 9-36406A proposes reducing the electrode thickness to lower the stress generated in the electrode thereby to prevent reduction of performance of a photoelectric conversion element. However, reduction in photoelectric conversion performance is still unavoidable with this method when the photoelectric conversion element has a large area or when the electrode has a large stress even with a reduced thickness.

JP 2008-72090A (corresponding to US2008/0035965A1) discloses a structure including a multi-layered charge blocking layer between a photoelectric conversion layer and each of the opposite electrodes but does not discuss reduction of photoelectric conversion performance due to the stress generated in the electrodes and a countermeasure against it.

The present invention is contemplated to provide a photoelectric conversion element and a solid state imaging device that are protected against performance reduction due to the stress generated in the electrode.

The present invention provides in its first aspect (1) a photoelectric conversion element including a pair of electrodes, a photoelectric conversion layer between the pair of electrodes, and a stress buffer layer between the photoelectric conversion layer and at least one of the electrodes. At least part of the stress buffer layer has a stack structure containing a crystalline sublayer.

The invention provides photoelectric conversion elements (2) to (11) as preferred embodiments of the photoelectric conversion element (1).
(2) The photoelectric conversion element (1), in which the buffer layer has the crystalline sublayer alternating with an amorphous sublayer.
(3) The photoelectric conversion element (2), in which the buffer layer has two alternations of the crystalline sublayer with the amorphous sublayer.
(4) The photoelectric conversion element (2) or (3), in which the crystalline sublayer and the amorphous sublayer each have a thickness of 0.5 to 200 nm.
(5) The photoelectric conversion element (1) to (4), in which the stress buffer layer serves as a charge blocking layer that reduces charge injection from one of the electrodes into the photoelectric conversion layer on voltage application to the pair of electrodes.
(6) The photoelectric conversion element (1) to (5), in which the quotient of a voltage externally applied to the electrodes divided by the distance between the electrodes is in the range of from 1.0×10⁵ V/cm to 1.0×10⁷ V/cm.
(7) The photoelectric conversion element (1) to (6), in which the photoelectric conversion layer further includes a semiconductor substrate having at least one of the photoelectric conversion layer thereover, a charge storage part in the semiconductor substrate where a charge generated in the photoelectric conversion layer is stored, and a connector electrically connecting the charge storage part to one of the electrodes that collects the charge.
(8) The photoelectric conversion element (7), further including an in-substrate photoelectric conversion part in the substrate where incident light transmitted through the photoelectric conversion layer is absorbed, and a charge is generated in response to the light and stored.
(9) The photoelectric conversion element (8), in which the in-substrate photoelectric conversion part is formed of a stack of a plurality of photodiodes absorbing different colors of light.
(10) The photoelectric conversion element (8), in which the in-substrate photoelectric conversion part is formed of a plurality of photodiodes absorbing different colors of light, the photodiodes being arranged in a direction perpendicular to the direction of the incident light.
(11) The photoelectric conversion element (9), in which the number of the at least one of the photoelectric conversion layer over the semiconductor substrate is one, the stack of photodiodes contains a blue-sensitive photodiode having its pn junction located at the depth where blue light is absorbed and a red-sensitive photodiode having its pn junction located at the depth where red light is absorbed, and the photoelectric conversion layer absorbs green light.

The invention also provides in its second aspect a solid state imaging device having an array of a large number of the photoelectric conversion elements according to any one of (7) to (11) described above. The solid state imaging device further has signal reading parts reading out a signal corresponding to the charge stored in the charge storage part of the photoelectric conversion elements.

The photoelectric conversion element according to the invention has a stress buffer layer at least part of which has a stack structure containing a crystalline sublayer between at least one of the electrodes and the photoelectric conversion layer. The stress buffer layer buffers the stress generated in the electrode. Therefore, cracking, delamination or deformation is prevented from occurring along the interface between the electrode and the photoelectric conversion layer or between the electrode and a blocking layer. The provision of the stress buffer layer eliminates the need to reduce the electrode thickness so that disadvantages that might be otherwise caused by an increased resistance of the electrode, such as reduction in voltage or response speed, are avoided.

The present invention provides a photoelectric conversion element and a solid state imaging device that are prevented from performance reduction caused by the stress generated in the electrode.

### BRIEF DESCRIPTION OF THE DRAWINGS

FIG. 1 is a schematic cross-section of a photoelectric conversion element incorporating a first embodiment of the invention,

FIG. 2 is a schematic cross-section of a photoelectric conversion element showing a modification to the first embodiment.

FIG. 3 is a schematic fragmentary cross-section of a solid state imaging device incorporating a second embodiment of the invention.

FIG. 4 is a schematic fragmentary cross-section of a solid state imaging device incorporating a third embodiment of the invention.

FIG. 5 is a schematic fragmentary cross-section of a solid state imaging device incorporating a fourth embodiment of the invention.

FIG. 6 is a schematic fragmentary cross-section of a solid state imaging device incorporating a fifth embodiment of the invention.

### DETAILED DESCRIPTION OF THE INVENTION

The invention will be described based on its preferred embodiments with reference to the accompanying drawing.

### [I] First Embodiment

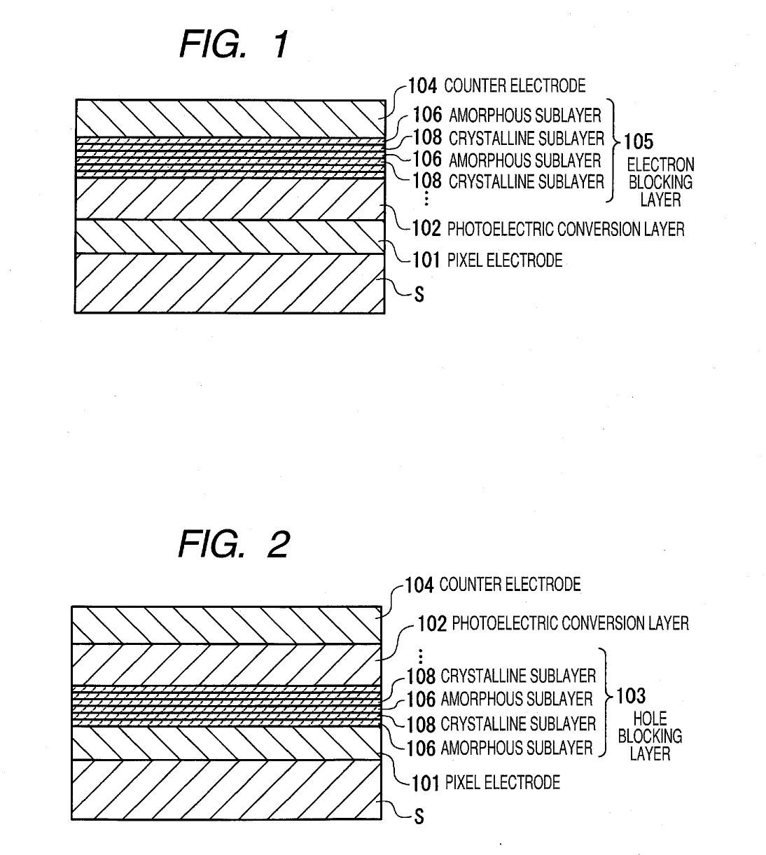

FIG. 1 is a schematic cross-section of a photoelectric conversion element according to a first embodiment of the invention. FIG. 2 is a modification of the photoelectric conversion element of FIG. 1.

The photoelectric conversion element illustrated in FIG. 1 includes a substrate S, a lower electrode (pixel electrode) 101 formed on the substrate S, a photoelectric conversion layer 102 formed on the lower electrode 101, an electron blocking layer 105 formed on the photoelectric conversion layer 102, and an upper electrode (counter electrode) 104 formed on the electron blocking layer 105.

The photoelectric conversion element illustrated in FIG. 2 includes a substrate S, a lower electrode (pixel electrode) 101 formed on the substrate S, a hole blocking layer 103 formed on the lower electrode 101, a photoelectric conversion layer 102 formed on the hole blocking layer 103, and an upper electrode (counter electrode) 104 formed on the photoelectric conversion layer 102. In what follows, the hole blocking layer 105 and the electron blocking layer 103 will also be inclusively referred to as a charge blocking layer.

The photoelectric conversion element of FIG. 1 is configured to receive light incident on the side of the upper electrode 104. It is also configured such that a bias voltage is applied between the opposite electrodes 101 and 104 so that the electrons (negative charges) and the holes (positive charges) photogenerated in the photoelectric conversion layer 102 are swept toward the upper electrode 104 and the lower electrode 101, respectively. Namely, the upper electrode 104 serves as an electron collecting electrode, and the lower electrode as a hole collecting electrode.

The upper electrode 104 should be made of a transparent conductive material to allow light to impinge on the photoelectric conversion layer 102. As used herein, the term “transparent” is intended to mean the ability of an electrode to allow more than about 80% of visible light in the range of, e.g., from about 420 to 660 nm to pass therethrough. It is preferred to use indium tin oxide (ITO) as a transparent conductive material.

The lower electrode 101 should be of a conductive material but does not need to be transparent. In some applications, nevertheless, the photoelectric conversion element of FIG. 1 is required to allow light to pass through the lower electrode 101 as with the case hereinafter described. It is therefore preferred that the lower electrode 101 be also made of a transparent conductive material. Similarly to the upper electrode 104, it is preferred to use ITO to make the lower electrode 101.

The photoelectric conversion element of FIG. 1 has an electron blocking layer 105 that provides a barrier against injection of charges (electrons in this particular embodiment) from the electrode when a voltage is applied to the opposing electrodes. The electron blocking layer 105 has a stack structure composed of alternations of an amorphous sublayer 106 and a crystalline sublayer 108 in the direction of from the upper electrode 104 to the photoelectric conversion layer 102. The electron blocking layer 105 functions as a stress buffer layer in the present embodiment.

The photoelectric conversion element illustrated in FIG. 2 has a hole blocking layer 103 that provides a barrier against injection of charges (holes in this particular embodiment) from the electrode when a voltage is applied to the opposing electrodes. The hole blocking layer 103 has a stack structure composed of alternations of an amorphous sublayer 106 and a crystalline sublayer 108 in the direction of from the pixel electrode 101 to the photoelectric conversion layer 102. The hole blocking layer 103 functions as a stress buffer layer in the present embodiment.

The photoelectric conversion layer 102 is made of a material containing an organic material having a photoelectric conversion function. Useful organic materials include various organic semiconductor materials such as those used in electrophotographic light-sensitive materials. Preferred of them are those having a quinacridone skeleton and those having a phthalocyanine skeleton in view of their high photoelectric conversion performance, high ability of spectral separation of light, high durability against long-term exposure to light, ease of deposition by vacuum evaporation, and so on.

In an example, a photoelectric conversion layer 102 made of quinacridone of formula below absorbs light of green wavelengths and generates corresponding charges.

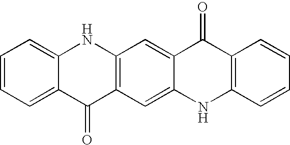

In another example, a photoelectric conversion layer 102 made of zinc phthalocyanine of formula below absorbs light of red wavelengths and generates corresponding charges.

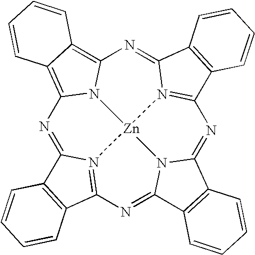

The organic material making up the photoelectric conversion layer 102 preferably contains at least one of an organic p-type semiconductor and an organic n-type semiconductor. Particularly preferred examples of the organic p-type and n-type semiconductors include quinacridone derivatives, naphthalene derivatives, anthracene derivatives, phenanthrene derivatives, tetracene derivatives, pyrene derivatives, perylene derivatives, and fluoranthene derivatives.

An organic p type semiconductor (compound) is a donating organic semiconductor (compound), i.e., an organic compound having electron donating character, which is mostly exemplified by a hole transporting organic material. In some detail, when two organic materials are used in contact with each other, the material having a smaller ionization potential is an electron donating compound. Any electron donating organic compound may be used, including triarylamine compounds, benzidine compounds, pyrazoline compounds, styrylamine compounds, hydrazone compounds, triphenylmethane compounds, carbazole compounds, polysilane compounds, thiophene compounds, phthalocyanine compounds, cyanine compounds, merocyanine compounds, oxonol compounds, polyamine compounds, indole compounds, pyrrole compounds, pyrazole compounds, polyarylene compounds, fused aromatic carbocyclic compounds (e.g., naphthalene derivatives, anthracene derivatives, phenanthrene derivatives, tetracene derivatives, pyrene derivatives, perylene derivatives, and fluoranthene derivatives), and metal complexes having a nitrogen-containing heterocyclic compound as a ligand. In addition, any organic compounds having a smaller ionization potential than an organic compound used as an n type, electron-accepting organic compound may be used as a donating organic semiconductor.

The organic n type semiconductor (compound) is an accepting organic semiconductor (compound), i.e., an organic compound having electron accepting character, which is mostly exemplified by an electron transporting organic compound. In some detail, when two organic compounds are used in contact with each other, the compound having larger electron affinity is an electron accepting compound. Any compound having electron accepting character may be used, including fused aromatic carbocyclic compounds (e.g., naphthalene derivatives, anthracene derivatives, phenanthrene derivatives, tetracene derivatives, pyrene derivatives, perylene derivatives, and fluoranthene derivatives), nitrogen-, oxygen- or sulfur-containing 5- to 7-membered heterocyclic compounds (e.g., pyridine, pyrazine, pyrimidine, pyridazine, triazine, quinoline, quinoxaline, quinazoline, phthalazine, cinnoline, isoquinoline, pteridine, acridine, phenazine, phenanthroline, tetrazole, pyrazole, imidazole, thiazole, oxazole, indazole, benzimidazole, benzotriazole, benzoxazole, benzothiazole, carbazole, purine, triazolopyridazine, triazolopyrimidine, tetraazaindene, oxadiazole, imidazopyridine, pyralidine, pyrrolopyridine, thiadiazolopyridine, dibenzazepin, and tribenzazepin), polyarylene compounds, fluorene compounds, cyclopentadiene compounds, silyl compounds, and complexes having a nitrogen-containing heterocyclic compound as a ligand. In addition, any organic compounds having larger electron affinity than an organic compound used as an electron-donating organic compound may be used as an accepting organic semiconductor.

Any p type or n type organic dyes are useful. Examples of preferred organic dyes include, but are not limited to, cyanine dyes, styryl dyes, hemicyanine dyes, merocyanine dyes (including zeromethine merocyanine (simple merocyanine)), trinuclear merocyanine dyes, tetranuclear merocyanine dyes, rhodacyanine dyes, complex cyanine dyes, complex merocyanine dyes, allopolar dyes, oxonol dyes, hemioxonol dyes, squarylium dyes, chroconium dyes, azamethine dyes, coumarin dyes, arylidene dyes, anthraquinone dyes, triphenylmethane dyes, azo dyes, azomethine dyes, spiro compounds, metallocene dyes, fluorenone dyes, flugide dyes, perylene dyes, phenazine dyes, phenothiazine dyes, quinone dyes, indigo dyes, diphenylmethane dyes, polyene dyes, acridine dyes, acridinone dyes, diphenylamine dyes, quinacridone dyes, quinophthalone dyes, phenoxazine dyes, phthaloperylene dyes, porphyrin dyes, chlorophyll dyes, phthalocyanine dyes, metal complex dyes, and fused aromatic carbocyclic compound dyes (e.g., naphthalene derivatives, anthracene derivatives, phenanthrene derivatives, tetracene derivatives, pyrene derivatives, perylene derivatives, and fluoranthene derivatives).

The metal complex compound is a metal complex having a ligand containing at least one of nitrogen, oxygen, and sulfur atoms coordinated to a center metal atom thereof. Preferred examples of the center metal ion in the metal complex include, but are not limited to, a beryllium ion, a magnesium ion, an aluminum ion, a gallium ion, a zinc ion, an indium ion, and a tin ion, more preferably a beryllium ion, an aluminum ion, a gallium ion, and a zinc ion. Even more preferred are an aluminum ion and a zinc ion. The metal complex may have various known ligands, including those described in H. Yersin, Photochemistry and Photophysics of Coordination Compounds, Springer-Verlag (1987) and Akio Yamamoto, Yuki Kinzoku Kagaku-Kiso to Ohyo, Shokabo Publishing Co., Ltd. (1982).

The ligand is preferably a nitrogen-containing heterocyclic ligand preferably having 1 to 30 carbon atoms, more preferably 2 to 20 carbon atoms, even more preferably 3 to 15 carbon atoms. The ligand may be monodentate or polydentate, preferablybidentate. Examples of useful ligands include a pyridine ligand, a bipyridyl ligand, a quinolinol ligand, a hydroxyphenylazole ligand (e.g., hydroxyphenylbenzimidazole, hydroxyphenylbenzoxazole or hydroxyphenylimidazole), an alkoxy ligand (preferably having 1 to 30 carbon atoms, more preferably 1 to 20 carbon atoms, even more preferably 1 to 10 carbon atoms, e.g., methoxy, ethoxy, butoxy, or 2-ethylhexyloxy), an aryloxy ligand (preferably having 6 to 30 carbon atoms, more preferably 6 to 20 carbon atoms, even more preferably 6 to 12 carbon atoms, e.g., phenyloxy, 1-naphthyloxy, 2-naphthyloxy, 2,4,6-trimethylphenyloxy, or 4-biphenyloxy), a heteroaryloxy ligand (preferably having 1 to 30 carbon atoms, more preferably 1 to 20 carbon atoms, even more preferably 1 to 12 carbon atoms, e.g., pyridyloxy, pyrazyloxy, pyrimidyloxyor quinolyloxy), an alkylthio ligand (preferably having 1 to 30 carbon atoms, more preferably 1 to 20 carbon atoms, even more preferably 1 to 12 carbon atoms, e.g., methylthio or ethylthio), an arylthio ligand (preferably having 6 to 30 carbon atoms, more preferably 6 to 20 carbon atoms, even more preferably 6 to 12 carbon atoms, e.g., phenylthio), a heterocyclic thio ligand (preferably having 1 to 30 carbon atoms, more preferably 1 to 20 carbon atoms, even more preferably 1 to 12 carbon atoms, e.g., pyridylthio, 2-benzimidazolylthio, 2-benzoxazolylthio, or 2-benzothiazolylthio), and a siloxy ligand (preferably having 1 to 30 carbon atoms, more preferably 3 to 25 carbon atoms, even more preferably 6 to 20 carbon atoms, e.g., triphenylsiloxy, triethoxysiloxy or triisopropylsiloxy). Preferred of them are a nitrogen-containing heterocyclic ligand, an aryloxy ligand, a heterocyclic oxy ligand, and a siloxy ligand. Particularly preferred are a nitrogen-containing heterocyclic ligand, a heteroaryloxy ligand, and a siloxy ligand. More preferred are a nitrogen-containing heterocyclic ligand, an aryloxy ligand, and a siloxy ligand.

The stress buffer layer may have a stack structure containing, in at least part thereof, a crystalline sublayer. In the photoelectric conversion element illustrated in FIG. 1 or 2, part of the electron blocking layer 105 or the hole blocking layer 103 may have a stack structure containing a crystalline sublayer to serve as a stress buffer layer. It is only necessary to provide at least one stress buffer layer, which is between either one of the opposite electrodes 101 and 104 and the photoelectric conversion layer 102. The location where the stress buffer layer is provided is not limited to the electron blocking layer 105 or the hole blocking layer 103. A stress buffer layer independent of the charge blocking layer may be provided, or a part of a layer independent of the charge blocking layer may be designed to serve as a stress buffer layer. A stress buffer layer may be provided between the pixel electrode 101 and the photoelectric conversion layer 102 and also between the photoelectric conversion layer 102 and the upper electrode 104.

The crystalline sublayer that can be used in the stress buffer layer is preferably microcrystalline with grain boundaries or gaps rather than monocrystalline. A crystalline sublayer is considered to be capable of absorbing stress in its crystal grain boundaries or gaps at the interface with an amorphous layer. As used herein, the term “microcrystalline” refers to a state of a thin film characterized by (1) a crystal volume fraction of a few percent to 100 percent in an amorphous film matrix, the film being formed of an organic or inorganic material by resistance heating evaporation, electron beam evaporation, sputtering, chemical vapor deposition (CVD), or a wet film formation technique and (2) a crystal grain size of from a few angstroms to a few micrometers. The crystalline sublayer and the amorphous sublayer each preferably have a thickness of 0.5 to 200 nm.

The crystalline sublayer is preferably of a material having charge transport properties and capable of forming a microcrystalline film. Of organic materials those having high planarity and thereby showing large intermolecular force easily exhibit crystalline properties. Such materials are exemplified by organic pigments. Materials that form an amorphous layer when processed at room temperature may be usable provided that they exhibit a microcrystalline phase when formed into a thin film under heating, for example, when deposited on a heated substrate. There are many inorganic materials that provide a microcrystalline structure when formed into a thin film, and various inorganic materials may be used as long as necessary charge transport properties are secured. Inorganic oxides having charge transport properties and charge blocking properties are particularly preferred.

Amorphous materials that form the amorphous sublayer may be any of generally known organic or inorganic materials which exhibit charge transport properties. Materials which become microcrystalline when processed at room temperature but are capable of forming an amorphous layer when, for example, deposited on a cooled substrate are also usable. The sublayer alternating with the crystalline sublayer is not limited to an amorphous sublayer and may be a layer of any other materials capable of allowing the crystalline sublayer to absorb stress in the grain boundaries or gaps at the interface with the crystalline sublayer.

The photoelectric conversion elements of FIGS. 1 and 2 may have both the electron blocking layer 105 and the hole blocking layer 103. The electron blocking layer 105 and the hole blocking layer 103 may be exchanged for each other in accordance with the direction of voltage application.

To improve the photoelectric conversion efficiency, it is preferred that the quotient of a voltage externally applied between the upper electrode 104 and the lower electrode 101 divided by the distance between these electrodes be in the range of from 1.0×10⁵ V/cm to 1.0×10⁷ V/cm.

The charge blocking layer, if too thin, will fail to secure sufficient blocking properties. If it is too thick, on the other hand, the electric field to the photoelectric conversion layer will be weakened to reduce the photoelectric conversion efficiency. The thickness of the charge blocking layer is preferably 0.01 to 15 μm, more preferably 0.03 to 1 μm, even more preferably 0.05 to 0.2 μm.

The photoelectric conversion element of the present embodiment includes a stress buffer layer having a stack structure containing a crystalline sublayer 108 between the photoelectric conversion layer 102 and the electrode 101 or 104 so that the stress generated in the electrode is buffered by the stress buffer layer. The photoelectric conversion element is therefore prevented from suffering cracking, delamination, or deformation at the interface between the photoelectric conversion layer 102 and the electrode 101 or 104. Furthermore, the provision of the stress buffer layer eliminates the need to reduce the thickness of the electrode. As a result, disadvantages due to an increase of resistance of the electrode that might otherwise occur, such as reduction in voltage and reduction in response speed, can be averted.

In the case where the stress buffer layer is independently provided between the electrode and the charge blocking layer, cracking, delamination or deformation is prevented from occurring at the interface between the electrode and the charge blocking layer.

The invention will further be described with respect to its second to fifth embodiments, in which the above described photoelectric conversion element is superposed over a substrate to fabricate an image sensor. Parts or members identified with the same numerals as in the foregoing first embodiment and its modification may be identical and will not be redundantly described.

### [II] Second Embodiment

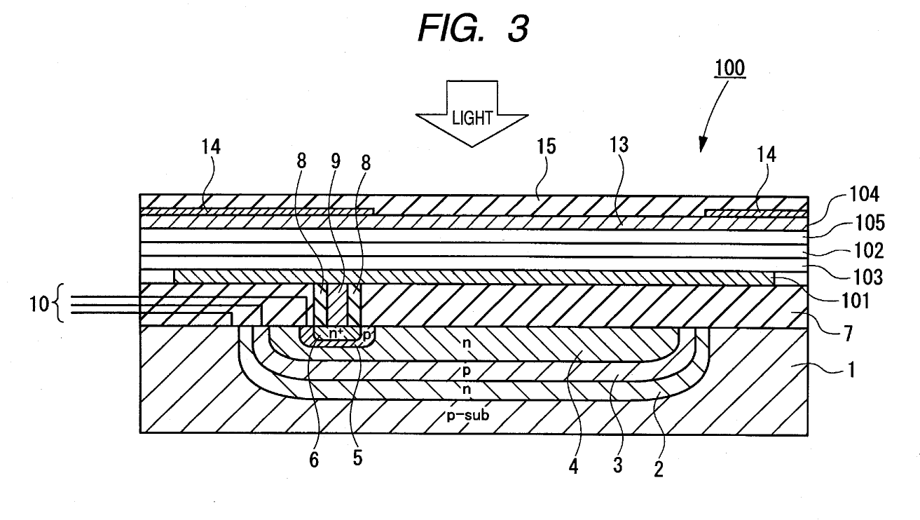

FIG. 3 is a fragmentary, schematic cross-section of a single pixel of a solid state imaging device 100 incorporating the second embodiment of the invention. Parts or members identified with the same numerals as in FIGS. 1 and 2 are identical.

The solid state imaging device 100 is composed of two-dimensionally arrayed pixels, one of which is illustrated in FIG. 3. One pixel outputs one signal that provides one pixel datum of image data.

The pixel of the solid state imaging device 100 shown in FIG. 3 includes a p type silicon substrate 1 and a photoelectric conversion element composed of a transparent insulating layer 7 formed on the p type silicon substrate, a lower electrode 101 formed on the insulating layer 7, a hole blocking layer 103 formed on the lower electrode 101, a photoelectric conversion layer 102 formed on the hole blocking layer 103, an electron blocking layer 105 formed on the photoelectric conversion layer 102, and an upper electrode 104 formed on the electron blocking layer 105. A light shielding layer 14 having an opening is provided on the photoelectric conversion element. A transparent insulating layer 15 is provided on the upper electrode 104. A stress buffer layer having a stack structure containing a crystalline sublayer is provided in at least one of the electron blocking layer 105 and the hole blocking layer 103.

Within the p type silicon substrate 1 are formed an n type impurity doped region (hereinafter “n region”) 4, a p type impurity doped region (hereinafter “p region”) 3, and another n region 2 in the order described in the depth direction from the upper surface of the substrate 1. A region highly doped with n type impurity (hereinafter “n⁺ region”) 6 is formed in a surface portion of a shaded part of the n region 4 that is covered by the light shielding layer 14. The n⁺ region is surrounded by a p region 5.

The pn junction between the n region 4 and the p region 3 is formed at a depth where blue light is absorbed, specifically about 0.2 μm from the surface of the p type silicon substrate. The n region 4 and the p region 3 thus form a photodiode that absorbs blue light and stores charges in response to the absorbed blue light (hereinafter “B photodiode”).

The pn junction between the n region 2 and the p type silicon substrate 1 is at a depth where red light is absorbed, specifically about 2 μm from the surface of the p type silicon substrate. The n region 2 and the p type silicon substrate thus form a photodiode that absorbs red light and stores charges in response thereto (hereinafter “R photodiode”).

The n⁺ region 6 is electrically connected to the lower electrode 101 via a connector 9 formed in a through-hole of the insulating layer 7. The holes swept into the lower electrode 101 are recombined with the electrons of the n⁺ region 6. As a result, the electrons accumulated in the n⁺ region 6 upon resetting decrease in response to the number of the collected holes. The connector 9 is electrically insulated from other than the lower electrode 101 and the n⁺ region 6 by the insulator 8.

The electrons stored in the n region 2 are converted to a signal corresponding to the amount of charges by an MOS circuit (not shown) having an n-channel MOS transistor formed in the p type silicon substrate 1. The electrons stored in the n region 4 are converted to a signal corresponding to the amount of charges by an MOS circuit (not shown) having an n-channel MOS transistor formed in the p region 3. The electrons stored in the n⁻ region 6 are converted to a signal corresponding to the charges by an MOS circuit (not shown) having an n-channel MOS transistor formed in the p region 5. These signals are outputted from the solid state imaging device 100. Each MOS circuit is connected to a signal reading pad (not shown) through respective wires 10. An extractor electrode may be provided in the n regions 2 and 4, and a predetermined reset potential is applied thereto, whereby each region is depleted, and the capacity of each junction becomes infinitely small. The capacity generating at the respective junctions can thus be minimized.

So constructed, the solid state imaging device 100 converts green light G to electrical signals in its photoelectric conversion layer 102 and blue light B and red light R to respective electrical signals in the B photodiode and R photodiode, respectively, formed in its p type silicon substrate 1. Since light G is first absorbed in the upper photoelectric conversion layer, improved color separation is achieved between light B and light G and between light G and light R. This is a remarkable advantage over a solid state imaging device of the type in which three photodiodes are stacked in a silicon substrate to conduct BGR color separation within the silicon substrate.

The solid state imaging device 100 of the second embodiment has a stress buffer layer between the photoelectric conversion layer 102 and one or both of the pixel electrode 101 and the upper electrode 104. The stress buffer layer buffers the stress generated in the electrode 101 and/or the electrode 104 to prevent cracking, delamination or deformation from occurring at the interface between the photoelectric conversion layer 102 and the electrode 101 and/or the electrode 104.

### [III] Third Embodiment

The third embodiment provides a solid state imaging device of which each pixel is configured to detect two colors of light in a p type silicon substrate in which two photodiodes are not stacked in the substrate thickness direction as in FIG. 3 but arranged in a direction perpendicular to the direction of incident light.

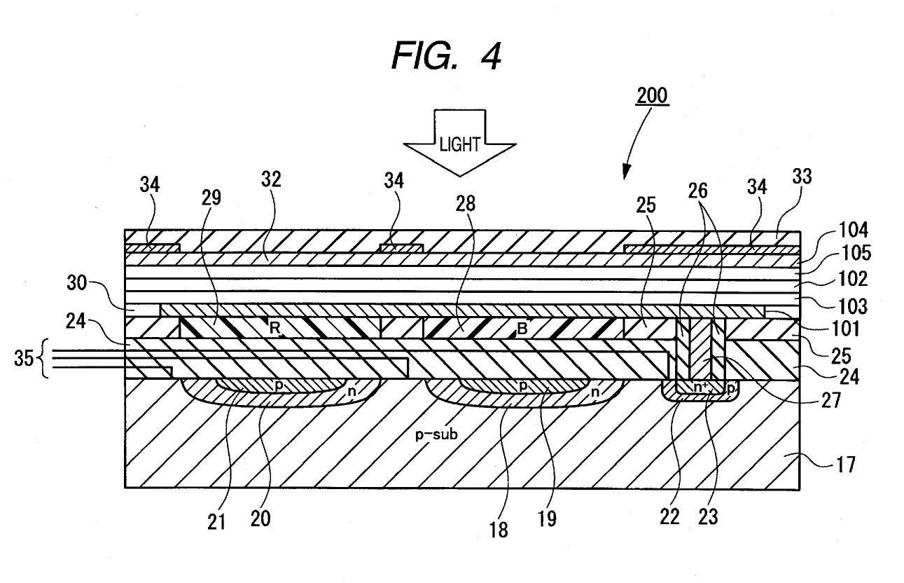

FIG. 4 is a schematic cross-section of a single pixel of a solid state imaging device 200 incorporating the third embodiment. Parts or members identified with the same numerals as in FIGS. 1 and 2 are identical.

Each pixel of the solid state imaging device 200 illustrated in FIG. 4 includes a p type silicon substrate 17 and a photoelectric conversion element. The photoelectric conversion element is composed of a lower electrode 101 formed above the p type silicon substrate 17, a hole blocking layer 103 formed on the lower electrode 101, a photoelectric conversion layer 102 formed on the hole blocking layer 103, an electron blocking layer 105 formed on the photoelectric conversion layer 102, and an upper electrode 104 formed on the electron blocking layer 105. A light shielding layer 34 having openings is provided on the photoelectric conversion element. A transparent insulating layer 33 is provided on the upper electrode 104. A stress buffer layer having a stack structure containing a crystalline sublayer is provided in at least one of the electron blocking layer 105 and the hole blocking layer 103.

A photodiode consisting of a p region 19 and an n region 18 and a photodiode consisting of a p region 21 and an n region 20 are formed in the surface portion of the p type silicon substrate 17. The two photodiodes are each in the area right below the openings of the light shielding layer 34 and juxtaposed to each other. Any planar direction on the surface of the p type silicon substrate 17 is perpendicular to the direction of incident light.

A color filter 28 transmitting light B is formed over the photodiode consisting of the p region 19 and the n region 18 with a transparent insulating layer 24 therebetween. The lower electrode 101 is formed on the color filter 28. A color filter 29 transmitting light R is formed over the photodiode consisting of the p region 21 and the n region 20 with the transparent insulating layer 24 therebetween. The lower electrode 101 is formed on the color filter 29. The color filters 28 and 29 are each surrounded by a transparent insulating layer 25.

The photodiode made of the p region 19 and the n region 18 functions as an in-substrate photoelectric conversion part that absorbs light B having passed through the color filter 28, produces electrons in response to the absorbed light B, and stores the produced electrons in its n region 18. The photodiode formed of the p region 21 and the n region 20 functions as an in-substrate photoelectric conversion part that absorbs right R having passed through the color filter 29 to produce electrons in response to the absorbed light R and stores the electrons in its n region 20.

An n⁺ region 23 is formed in a surface portion of a shaded part of the p type silicon substrate 17 that is covered by the light shielding layer 34. The n⁺ region 23 is surrounded by a p region 22.

The n^{|} region 23 is electrically connected to the lower electrode 101 via a connector 27 formed in a through-hole made through the insulating layers 24 and 25. The positive holes swept into the lower electrode 101 are recombined with the electrons of the n⁺ region 23. As a result, the electrons accumulated in n⁺ region 23 upon resetting decrease in response to the number of the collected holes. The connector 27 is electrically insulated from other than the lower electrode 101 and the n⁺ region 23 by an insulator 26.

The electrons stored in the n region 18 are converted to a signal corresponding to the amount of charges by an MOS circuit (not shown) having an n-channel MOS transistor formed in the p type silicon substrate 17. The electrons stored in the n region 20 are converted to a signal corresponding to the amount of charges by an MOS circuit (not shown) having an n-channel MOS transistor formed in the p type substrate 17. The electrons stored in the n⁺ region 23 are converted to a signal corresponding to the charges by an MOS circuit (not shown) having an n-channel MOS transistor formed in the p region 22. These signals are outputted from the solid state imaging device 200. Each MOS circuit is connected to a signal reading pad (not shown) through respective wires 35.

The signal reading part may be composed of a CCD and an amplifier instead of the MOS circuit. That is, the electrons stored in the n region 18, n region 20, and n⁺ region 24 may be read out by a CCD formed in the p type silicon substrate 17 and transferred to an amplifier, and signals corresponding to the electrons are outputted from the amplifier.

While the signal reading part may be a CCD system or a CMOS system, the CMOS system is preferred in terms of power consumption, high-speed reading, pixel addition, partial reading, and so forth.

While in the embodiment illustrated in FIG. 4 color separation between light R and light B is performed by using the color filters 28 and 29, color separation may be carried out by adjusting the depth of the pn junction between the n region 20 and the p region 21 and the depth of the pn junction between the n region 18 and the p region 19 in the p type silicon substrate 17 so that light R and light B may be absorbed by the respective photodiodes.

It is possible to form an inorganic photoelectric conversion part between the p type silicon substrate 17 and the lower electrode 101, for example, between the insulating layer 24 and the p type silicon substrate 17, the inorganic photoelectric conversion part being made of an inorganic material capable of absorbing light having passed through the photoelectric conversion layer 102, generating charges corresponding to the light, and storing the charges. In this case, an MOS circuit for reading signals corresponding to the charges stored in the charge storage region of the inorganic photoelectric conversion part is formed in the p type silicon substrate 17, and a wire 35 is connected to the MOS circuit.

In a modification of the third embodiment, the solid state imaging device may have only one photodiode in the p type silicon substrate 17 and a stack of a plurality of photoelectric conversion parts over the p type silicon substrate 17. In another modification, the solid state imaging device may have a plurality of photodiodes in the p type silicon substrate 17 and a plurality of photoelectric conversion parts over the p type silicon substrate 17. Where it is unnecessary to form a color image, the solid state imaging device may have one photodiode in the p type silicon substrate 17 and one photoelectric conversion part above the substrate 17.

According to the third embodiment, the stress generated in the electrode 101 and/or the electrode 104 can be buffered by at least one stress buffer layer provided between the photoelectric conversion layer 102 and the pixel electrode 101 and/or the upper electrode 104. The solid state imaging device of the third embodiment is therefore prevented from suffering from cracking, delamination, or deformation at the interface between the photoelectric conversion layer 102 and the electrode 101 and/or 104.

### [IV] Fourth Embodiment

The fourth embodiment of the invention provides a solid state imaging device each pixel of which has no photodiode in the silicon substrate but a plurality of (e.g., three in this particular embodiment) photoelectric conversion elements formed over a silicon substrate.

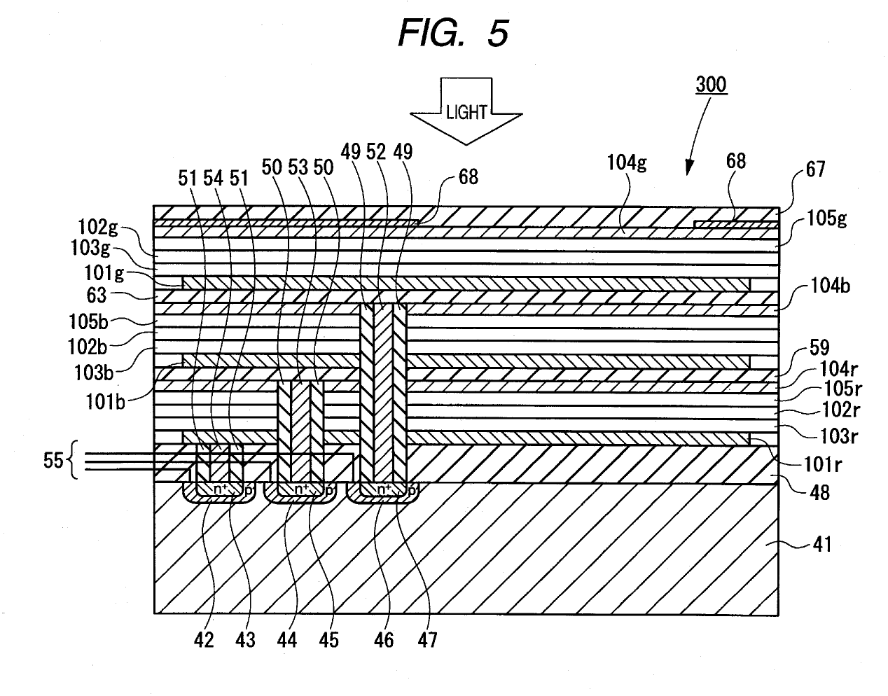

FIG. 5 is a schematic cross-section of a single pixel of a solid state imaging device 300 incorporating the fourth embodiment. Each pixel of the solid state imaging device 300 illustrated in FIG. 5 includes a p type silicon substrate 41 and an R photoelectric conversion element, a B photoelectric conversion element, and a G photoelectric conversion element stacked in this order over the substrate 41.

The R photoelectric conversion element, which is provided over the silicon substrate 41, includes a lower electrode 101r, a hole blocking layer 103r formed on the lower electrode 101r, a photoelectric conversion layer 102r formed on the hole blocking layer 103r, an electron blocking layer 105r formed on the photoelectric conversion layer 102r, and an upper electrode 104r formed on the electron blocking layer 105r. At least one of the hole blocking layer 103r and the electron blocking layer 105r is designed to serve as a stress buffer layer.

The B photoelectric conversion element includes a lower electrode 101b, a hole blocking layer 103b formed on the lower electrode 101b, a photoelectric conversion layer 102b formed on the hole blocking layer 103b, an electron blocking layer 105b formed on the photoelectric conversion layer 102b, and an upper electrode 104b formed on the electron blocking layer 105b. At least one of the hole blocking layer 103b and the electron blocking layer 105b is designed to serve as a stress buffer layer.

The G photoelectric conversion element includes a lower electrode 101g, a hole blocking layer 103g formed on the lower electrode 101g, a photoelectric conversion layer 102g formed on the hole blocking layer 103g, an electron blocking layer 105g formed on the photoelectric conversion layer 102g, and an upper electrode 104g formed on the electron blocking layer 105g. At least one of the hole blocking layer 103g and the electron blocking layer 105g is designed to serve as a stress buffer layer. The R, B, and G photoelectric conversion elements are stacked in this order over the silicon substrate 41 with their lower electrodes facing down to the substrate 41.

A transparent insulating layer 59 is formed between the upper electrode 104r of the R photoelectric conversion element and the lower electrode 101b of the B photoelectric conversion element, and a transparent insulating layer 63 is formed between the upper electrode 104b of the B photoelectric conversion element and the lower electrode 101g of the G photoelectric conversion element. A light shielding layer 68 having an opening is formed on the upper electrode 104g of the G photoelectric conversion element. A transparent insulating layer 67 is formed to cover the light shielding layer 67 and the exposed part of the upper electrode 104g.

The lower electrodes, photoelectric conversion layers, hole blocking layers, electron blocking layers, and upper electrodes used in the R, G, and B photoelectric conversion elements are equal to those used in FIG. 1, except that the photoelectric conversion layers 102g, 102b, and 102r contain organic materials absorbing green, blue, and red light, respectively, and generating electrons and holes in response to the respective light rays.

In surface portions of a shaded part of the silicon substrate 41 that is covered by the light shielding layer 68, there are formed n⁺ regions 43, 45, and 47 are formed. The n⁺ regions 43, 45, and 47 are each surrounded by p regions 42, 44, and 46, respectively.

The n⁺ region 43 is electrically connected to the lower electrode 101r via a connector 54 formed in a through-hole made through the insulating layer 48. The positive holes swept into the lower electrode 101r are recombined with the electrons of the n⁺ region 43. As a result, the electrons accumulated in n⁺ region 43 upon resetting decrease in response to the number of the collected holes. The connector 54 is electrically insulated from other than the lower electrode 101r and the n⁺ region 43 by an insulator 51.

The n⁺ region 45 is electrically connected to the lower electrode 101b via a connector 53 formed in a through-hole made through the insulating layer 48, the R photoelectric conversion element, and the insulating layer 59. The positive holes swept into the lower electrode 101b are recombined with the electrons of the n⁺ region 45. As a result, the electrons accumulated in n⁺ region 45 upon resetting decrease in response to the number of the collected holes. The connector 53 is electrically insulated from other than the lower electrode 101b and the n⁺ region 45 by an insulator 50.

The n⁺ region 47 is electrically connected to the lower electrode 101g via a connector 52 formed in a through-hole made through an insulating layer 48, the R photoelectric conversion element, the insulating layer 59, the B photoelectric conversion element, and the insulating layer 63. The holes swept into the lower electrode 101g are recombined with the electrons of the n⁺ region 47. As a result, the electrons accumulated in n⁺ region 47 upon resetting decrease in response to the number of the collected holes. The connector 52 is electrically insulated from other than the lower electrode 101g and the n⁺ region 47 by an insulator 549.

The electrons stored in the n⁺ region 43 are converted to a signal corresponding to the amount of charges by an MOS circuit (not shown) having an n-channel MOS transistor formed in the p region 42. The electrons stored in the n⁺ region 45 are converted to a signal corresponding to the amount of charges by an MOS circuit (not shown) having an n-channel MOS transistor formed in the p region 44. The electrons stored in the n⁺ region 47 are converted to a signal corresponding to the charges by an MOS circuit (not shown) having an n-channel MOS transistor formed in the p region 46. These signals are outputted from the solid state imaging device 300. Each MOS circuit is connected to a signal reading pad (not shown) through respective wires 55. The signal reading part may be composed of a CCD and an amplifier instead of the MOS circuit. That is, the electrons stored in the n⁺ regions 43, 45, and 47 may be read out by a CCD formed in the silicon substrate 41 and transferred to an amplifier, and signals corresponding to the electrons are outputted from the amplifier.

As used herein, the phrase “photoelectric conversion layer absorbing blue light B” and its equivalents means a photoelectric conversion layer capable of absorbing at least light of 400 to 500 nm, preferably having a percent absorption of at least 50% at the peak wavelength in that range. The phrase “photoelectric conversion layer absorbing green light G” and its equivalents, as used herein, means a photoelectric conversion layer capable of absorbing at least light of 500 to 600 nm, preferably having a percent absorption of at least 50% at the peak wavelength in that range. The phrase “photoelectric conversion layer absorbing red light R” and its equivalents, as used herein, means a photoelectric conversion layer capable of absorbing at least light of 600 to 700 nm, preferably having a percent absorption of at least 50% at the peak wavelength in that range.

The solid state imaging device 300 of the fourth embodiment has a stress buffer layer between each of the photoelectric conversion layers (i.e., 102r, 102g, and 102b) and at least one of the respective pixel electrodes (i.e., 101r, 101g, and 101b) and the respective upper electrodes (i.e., 104r, 104g, and 104g). The stress generated in the pixel electrodes 101r, 101g, and 101b and/or the upper electrode 104r, 104g, and 104b is buffered by the respective stress buffer layers. The solid state imaging device 300 is therefore prevented from suffering from cracking, delamination, or deformation at the interfaces between the photoelectric conversion layers 102r, 102g, and 102b and the pixel electrodes 101r, 101g, and 101b and/or the upper electrodes 104r, 104g, and 104b.

### [V] Fifth Embodiment

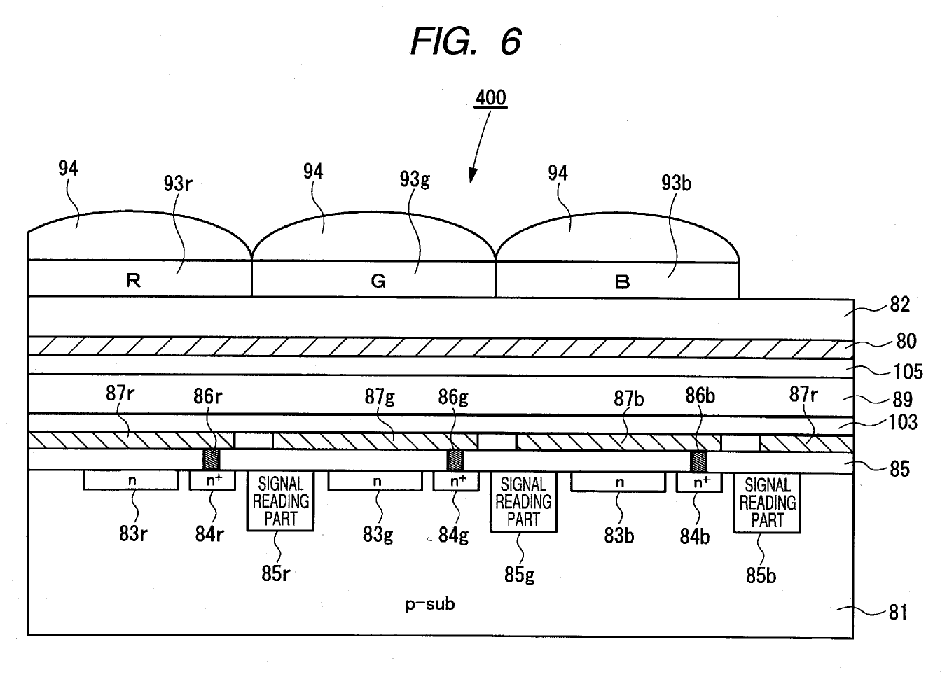

FIG. 6 is a schematic cross-section of a solid state imaging device 400 incorporating the fifth embodiment of the invention. The solid state imaging device 400 has a p type silicon substrate 81 and a large number of color filters of three kinds, color filters 93r passing mainly light of red wavelengths, color filters 93g passing mainly light of green wavelengths, and color filters 93b passing mainly light of blue wavelengths, two-dimensionally arrayed above the substrate 81 in both a first direction and a second direction perpendicular to the first direction.

The color filter 93r may be of any known materials. Such materials pass not only red light but part of infrared light. The color filter 93g may be of any known materials. Such materials pass not only green light but part of infrared light. The color filter 93b may be of any known materials. Such materials pass not only blue light but part of infrared light.

The color filters 93r, 93g, and 93b may be arrayed in accordance with the color filter arrays adopted in known single-plate solid state imaging devices, such as a Bayer array, a vertical stripe array, and a horizontal stripe array.

An n region 83r is formed below the color filter 93r. The pn junction between the n region 83r and the p type silicon substrate 81 form an R photoelectric conversion element corresponding to the color filter 93r.

An n region 83g is formed under the color filter 93g. The pn junction between the n region 83g and the p type silicon substrate 81 form a G photoelectric conversion element corresponding to the color filter 93g.

An n region 83b is formed under the color filter 93b. The pn junction between the n region 83b and the p type silicon substrate 81 form a G photoelectric conversion element corresponding to the color filter 93b.

A lower electrode 87r performing the same function as the lower electrode 101 in FIG. 1 is formed over the n region 83r. A lower electrode 87g performing the same function as the lower electrode 101 in FIG. 1 is formed over the n region 83g. A lower electrode 87b performing the same function as the lower electrode 101 in FIG. 1 is formed over the n region 83b. The lower electrodes 87r, 87g, and 87b are separate from one another and located below the color filters 93r, 93g, and 93b, respectively. The lower electrodes 87r, 87g, and 87b are made of a material transparent to visible light and infrared light, such as indium tin oxide (ITO) or indium zinc oxide (IZO), and separated from one another via an insulating layer.

A single monolithic photoelectric conversion layer 89 which absorbs mainly infrared light of 580 nm or longer wavelengths and generates charges in response to the light absorbed while passing light of other wavelengths in the visible region (e.g., about 380 to 580 nm) (performing the same function as the photoelectric conversion layer 102 of FIG. 1) is formed over the lower electrodes 87r, 87g, and 87b to be shared by these lower electrodes. The photoelectric conversion layer 89 is made of, e.g., a phthalocyanine organic material or a naphthalocyanine organic material.

A single monolithic upper electrode 80 having the same function as the upper electrode 104 of FIG. 1 is formed over the photoelectric conversion layer 89 to be shared by the color filters 93r, 93g, and 93b. The upper electrode 80 is made of a material transparent to visible and infrared light, e.g., ITO or IZO. An electron blocking layer 105 having the same function as the electron blocking layer 105 of FIG. 1 is formed between the photoelectric conversion layer 89 and the upper electrode 80. A hole blocking layer 103 is formed between the photoelectric conversion layer 89 and the lower electrodes 87r, 87g, and 87b. At least one of the hole blocking layer 103 and the electron blocking layer 105 is designed to serve as a stress buffer layer.

The lower electrode 87r, the opposite upper electrode 80, and the part of the photoelectric conversion layer 89 sandwiched therebetween compose an R photoelectric conversion element corresponding to the color filter 93r. The lower electrode 87g, the opposite upper electrode 80, and the part of the photoelectric conversion layer 89 sandwiched therebetween compose a G photoelectric conversion element corresponding to the color filter 93g. Likewise, the lower electrode 87b, the opposite upper electrode 80, and the part of the photoelectric conversion layer 89 sandwiched therebetween compose a B photoelectric conversion element corresponding to the color filter 93b. Seeing that the R, G, and B photoelectric conversion elements are on the upper side of the semiconductor substrate, they will hereinafter be referred to as on-substrate R, G, and B photoelectric conversion elements, respectively.

By the n region 83r is formed an n^{|} region 84r, which is electrically connected to the lower electrode 87r of the on-substrate R photoelectric conversion element. To prevent light from entering the n⁺ region 84r, a light shielding layer is preferably provided on the n⁺ region 84r.

By the n region 83g is formed an n⁺ region 84g, which is electrically connected to the lower electrode 87g of the on-substrate G photoelectric conversion element. To prevent light from entering the n⁺ region 84g, a light shielding layer is preferably provided on the n⁺ region 84r.

By the n region 83b is formed an n⁺ region 84b, which is electrically connected to the lower electrode 87b of the on-substrate B photoelectric conversion element. To prevent light from entering the n⁺ region 84b, a light shielding layer is preferably provided on the n⁺ region 84b.

The electrical connection between the n⁺ region 84r and the lower electrode 87r is made by a metal connector 86r, e.g., of tungsten or aluminum, which is embedded in an insulating layer 85 transparent to visible and infrared light.

The electrical connection between the n⁺ region 84g and the lower electrode 87g is made by a metal connector 86g, e.g., of tungsten or aluminum, which is embedded in the insulating layer 85.

The electrical connection between the n⁺ region 84b and the lower electrode 87b is made by a metal connector 86b, e.g., of tungsten or aluminum, which is embedded in the insulating layer 85.

A signal reading part 85r comprising an n channel MOS transistor for reading the signals corresponding to the electrons stored in the n region 83r and the n⁺ region 84r, a signal reading part 85g comprising an n channel MOS transistor for reading the signals corresponding to the electrons stored in the n region 83g and the n⁺ region 84g, and a signal reading part 85b comprising an n channel MOS transistor for reading the signals corresponding to the electrons stored in the n region 83b and the n⁺ region 84b are formed in other than the areas where the n regions 83r, 83g, and 83b and the n⁺ regions 84R, 84g, and 84b are formed. Each of the signal reading parts 85r, 85g, and 85b may be composed of a CCD. It is preferred to provide a light shielding layer on the signal reading parts 85r, 85g, and 86b to prevent light from entering the signal reading parts 85r, 85g, and 86b.

The above described configuration allows for obtaining an RGB color image and an infrared image with the same resolution at the same time. The solid state imaging device of this embodiment is therefore applicable to an electronic endoscope and so on.

According to the fifth embodiment, the internal stress generated in the lower electrodes 87r, 87g, and 87b and/or the upper electrode 80 is buffered by the stress buffer layer(s) so that cracking, delamination, or deformation is prevented from occurring at the interfaces between the photoelectric conversion layer 89 and the lower electrodes 87r, 87g, and 87b and/or the upper electrode 80.

In the foregoing embodiments, any one of the photoelectric conversion parts described may be made of an organic semiconductor having an absorption spectral maximum in the near infrared region as a photoelectric conversion material. Such a photoelectric conversion material is preferably transparent to visible light, more preferably a tin phthalocyanine or a silicon naphthalocyanine.

### EXAMPLES

The present invention will now be illustrated in greater detail with reference to Examples.

### Example 1

A 25 mm×25 mm square ITO glass substrate was cleaned by ultrasonication successively in acetone, Semicoclean (from Furuuchi Chemical Corp.), isopropyl alcohol (IPA) each for 15 minutes, followed by cleaning in boiling IPA, followed by ultraviolet/ozone cleaning. The thus cleaned substrate was set in an inorganic film formation chamber of a vacuum evaporation system. After the chamber was evacuated to 1×10⁻⁴ Pa or a higher degree of vacuum, cerium oxide (CeO₂) of 99.99% purity (available from Furuuchi Chemical Corp.) was deposited on the ITO electrode while rotating the substrate holder at a rate of deposition of 1.0 Å/sec to form a hole blocking layer having a thickness of 500 Å. CeO₂ powder in the crucible was heated directly with tungsten filaments because CeO₂ needs high temperatures to evaporate. The substrate holder holding the substrate was transferred to an organic film formation chamber in vacuo, where 4-dicyanomethylene-2-methyl-6-(p-dimethylaminostyryl)-4H-pyran (DCM) having been sufficiently purified by sublimation was evaporation deposited at a rate of deposition of 3.0 Å/sec to a thickness of 1000 Å to form a photoelectric conversion layer.

Subsequently, nickel oxide (NiO) with 99.99% purity (available from Furuuchi Chemical Corp.) and EBM-1 shown below having been sufficiently purified by sublimation were alternately deposited at a rate of deposition of 1.0 Å/sec each to a thickness of 50 nm to form a stress buffer layer having an electron blocking function having two alternations of NiO sublayers and EBM-1 sublayers with a total thickness of 200 nm. NiO powder in the crucible was heated directly with tungsten filaments because NiO needs high temperatures to evaporate. Oxygen was introduced into the chamber at a rate of 10 sccm during the NiO deposition to control the oxygen content of the NiO sublayers. The thus formed NiO sublayers and EBM-1 sublayers were microcrystalline and amorphous, respectively.

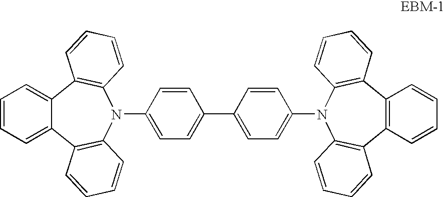

The substrate holder was transferred to a sputtering chamber in vacuo, where ITO was deposited on the stress buffer layer to a thickness of 500 Å to form a counter electrode. The effective area for photoelectric conversion formed by the opposite ITO electrodes was 2 mm by 2 mm. The resulting substrate was transferred, without being exposed to the atmosphere, to a glove box containing not more than 1 ppm moisture and not more than 1 ppm oxygen, where the substrate was sealed using a glass cover to which a moisture absorbent was attached and a UV curing resin.

The external quantum efficiency (EQE) of the resulting device was determined using a constant-energy quantum efficiency measuring system (power source meter: Keithley 2400) available from Optel. With an external electrical field of 5.0×10⁵ V/cm² applied, the dark current that flowed in the absence of light incident on the device and the light current that flowed in the presence of light on the device were measured to calculate the EQE. A 1.5 mm diameter circular area of the 2 mm by 2 mm photoelectric conversion area was irradiated with light of 480 nm, the maximum absorption wavelength of the photoelectric conversion DCM layer, and of 50 μW/cm². The resulting EQE was divided by the dark current density measured with no light irradiating the device to give an S/N.

### Example 2

A photoelectric conversion element was fabricated in the same manner as in Example 1, except that the stress buffer layer was formed by five alternations of NiO sublayers and EBM-1 sublayers each having a deposit thickness of 20 nm giving a total thickness of 200 nm. The S/N and other performance parameters of the device were determined in the same manner as in Example 1.

### Example 3

A photoelectric conversion element was fabricated in the same manner as in Example 1, except that the stress buffer layer was formed by ten alternations of NiO sublayers and EBM-1 sublayers each having a deposit thickness of 10 nm giving a total thickness of 200 nm. The S/N and other performance parameters of the device were determined in the same manner as in Example 1.

### Example 4

A substrate cleaned in the same manner as in Example 1 was transferred to an organic film formation chamber of a vacuum evaporation system. After the chamber was evacuated to 1×10⁻⁴ Pa or a higher degree of vacuum, EBM-1 having been purified by sublimation was deposited on the ITO electrode at a rate of deposition of 1.0 Å/sec to a thickness of 1000 Å while rotating the substrate holder to form an electron blocking layer. Subsequently, DCM having been sufficiently purified by sublimation was deposited at a rate of deposition of 3.0 Å/sec to a thickness of 1000 Å to form a photoelectric conversion layer.

Subsequently, naphthalene tetracarboxylic dianhydride (NTCDA) from Aldrich Chemical Company and CeO₂ were alternately deposited at a rate of deposition of 1.0 Å/sec each to a thickness of 20 nm to form a stress buffer layer having a hole blocking function having five alternations of NTCDA sublayers and CeO₂ sublayers with a total thickness of 200 nm. During deposition of CeO₂, the upper side of the substrate was strongly pressed by a copper block in which liquid nitrogen at '180° C. was circulated to keep the substrate temperature at or below −50° C. CeO₂ in the crucible was heated directly with tungsten filaments because CeO₂ needs high temperatures to evaporate. The deposition of NTCDA following the deposition of CeO₂ was performed after the substrate temperature returned to room temperature. The thus formed CeO₂ sublayers and NTCDA sublayers were amorphous and microcrystalline, respectively.

The substrate holder was transferred to a sputtering chamber in vacuo, where ITO was deposited on the stress buffer layer to a thickness of 500 Å to form a counter electrode. The effective area for photoelectric conversion formed by the opposite ITO electrodes was 2 mm by 2 mm. The resulting substrate was transferred, without being exposed to the atmosphere, to a glove box containing not more than 1 ppm moisture and not more than 1 ppm oxygen, where the substrate was sealed using a glass cover to which a moisture absorbent was attached and a UV curing resin.

The S/N and other performance parameters of the device were determined in the same manner as in Example 1.

### Comparative Example 1

A photoelectric conversion element was fabricated in the same manner as in Example 1, except for replacing the stress buffer layer with a 200 nm thick EBM-1 layer as an electron blocking layer. The S/N and other performance parameters of the device were determined in the same manner as in Example 1.

### Comparative Example 2

A photoelectric conversion element was fabricated in the same manner as in Example 1, except for replacing the stress buffer layer with a 200 nm thick NiO layer as an electron blocking layer. The S/N and other performance parameters of the device were determined in the same manner as in Example 1.

TABLE 1

| | | Photoelectric | |
|---|---|---|---|
| | Dark Current | Conversion | |
| | (A/cm²) | Efficiency (%) | S/N |
| Example 1 | 8.6E−10 | 11 | 1.3E+10 |
| Example 2 | 7.4E−10 | 11 | 1.5E+10 |
| Example 3 | 5.4E−10 | 10 | 1.9E+10 |
| Example 4 | 8.0E−10 | 8 | 1.0E+10 |
| Comparative | 5.6E−06 | 12 | 2.1E+06 |
| Example 1 | | | |
| Comparative | 8.9E−06 | 10 | 1.1E+06 |
| Example 2 | | | |

The results in Table 1 show the following. The photoelectric conversion element of Comparative Example 1, which has no NiO microcrystalline layer serving as a stress buffer layer, is liable to delamination between layers or partial breakage of a layer due to the stress in the ITO counter electrode. It follows that the opposing electrodes are brought closer in part to cause leak current and that an electrical field is concentrated to a partly nonuniform contact between layers, which induces charge injection from the electrode to cause an increase of dark current. The photoelectric conversion element of Comparative Example 2, which has an electron blocking layer made solely of microcrystalline NiO on which the counter electrode is directly deposited, is liable to concentration of an electrical field due to the nonuniform contact between the counter electrode and the microcrystalline layer. It follows that charges are injected through that part, resulting in an increase of dark current. In contrast, the photoelectric conversion elements of Examples 1 to 4, which have a stack of alternating microcrystalline sublayers and amorphous sublayers, drastically show a dark current inhibitory effect that allows for inhibition of dark current without reducing photoelectric conversion efficiency even with an increased thickness of the counter ITO electrode. Alternation of the microcrystalline sublayers with amorphous sublayers secures flatness, which also prevents nonuniform contact with the counter electrode and resultant dark current.

While the invention has been described with reference to its specific embodiments and examples, it should be understood that various changes and modifications can be mad therein without departing from the spirit and scope thereof.

What is claimed is:

1. A photoelectric conversion element comprising:
a pair of electrodes;
a photoelectric conversion layer provided between the pair of electrodes; and
a stress buffer layer provided between the photoelectric conversion layer and at least one of the electrodes,
wherein the stress buffer layer has a stack structure comprising a crystalline sublayer.

2. The photoelectric conversion element according to claim 1, wherein at least part of the stress buffer layer has the crystalline sublayer alternating with an amorphous sublayer.

3. The photoelectric conversion element according to claim 2, wherein the stress buffer layer comprising a stack structure having two alternations of the crystalline sublayer and the amorphous sublayer.

4. The photoelectric conversion element according to claim 2, wherein the crystalline sublayer and the amorphous sublayer each have a thickness of from 0.5 to 200 nm.

5. The photoelectric conversion element according to claim 1, wherein the stress buffer layer serves as a charge blocking layer that reduces charge injection from the at least one of the electrodes into the photoelectric conversion layer on voltage application to the pair of electrodes.

6. The photoelectric conversion element according to claim 1, wherein quotient of a voltage externally applied to the electrodes divided by a distance between the electrodes is in a range of from 1.0×10⁵ V/cm to 1.0×10⁷ V/cm.

7. The photoelectric conversion element according to claim 1, further comprising: a semiconductor substrate over which the photoelectric conversion layer is provided; a charge storage part provided in the semiconductor substrate where a charge generated in the photoelectric conversion layer is stored; and a connector electrically connecting the charge storage part to one of the electrodes that collects the charge.

8. The photoelectric conversion element according to claim 7, further comprising an in-substrate photoelectric conversion part provided in the semiconductor substrate where incident light transmitted through the photoelectric conversion layer is absorbed, and a charge is generated in response to the light and stored.

9. The photoelectric conversion element according to claim 8, wherein the in-substrate photoelectric conversion part is a stack of a plurality of photodiodes absorbing different colors of light.

10. The photoelectric conversion element according to claim 8, wherein the in-substrate photoelectric conversion part is a plurality of photodiodes absorbing different colors of light, the photodiodes being provided in a direction perpendicular to a direction of incident light.

11. The photoelectric conversion element according to claim 9, wherein the stack of photodiodes comprises a blue-sensitive photodiode having a pn junction located at a depth where blue light is absorbed and a red-sensitive photodiode having a pn junction located at a depth where red light is absorbed, and the photoelectric conversion layer absorbs green light.

12. A solid state imaging device comprising: an array of a plurality of the photoelectric conversion elements according to claim 7; and a signal reading part reading out a signal corresponding to the charge stored in the charge storage part of the photoelectric conversion elements.
